(19) United States
(12) Patent Application Publication
(10) Pub. No.: US 2007/0235058 A1
(43) Pub. Date: Oct. 11, 2007

(54) System and method for removing residue from a wafer processing chamber using sound waves

(76) Inventor: Daniel Harrington, Boise, ID (US)

Correspondence Address: FLETCHER YODER (MICRON TECHNOLOGY, INC.), P.O. BOX 692289, HOUSTON, TX, 77269-2289, US

(21) Appl. No.: 11/401,124

(22) Filed: Apr. 10, 2006

(51) Int. Cl. B08B 3/12; H01L 21/306; C23C 16/00

(52) U.S. Cl. 134/1; 118/722; 156/345.1

(57) ABSTRACT

Embodiments of the present technique relate to a system and method of removing residual particles from a wafer processing chamber. Specifically, embodiments of the present technique include performing a cleaning operation on a process chamber of a wafer processing system and utilizing sonic wave emissions to enhance cleansing. The sonic wave emissions dislodge accumulated particulate matter from the chamber, which increases removal of residue formed by the particulate matter from the chamber.

### BACKGROUND OF THE INVENTION

1. Field of the Invention

The present invention relates generally to processing semiconductor wafers to produce integrated circuits. More specifically, embodiments of the present technique pertain to a system and method for removing residue (e.g., etching residue and other built-up particulate matter) from interior surfaces of a wafer processing chamber.

2. Description of the Related Art

This section is intended to introduce the reader to various aspects of art that may be related to various aspects of the present invention, which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Procedures for processing a wafer (e.g., silicon wafer) to produce an integrated circuit typically include a number of manufacturing steps that sequentially form, shape, and modify layers of various materials on the wafer. Various techniques may be employed to grow or dispose various materials onto the wafer. Subsequent techniques may be employed throughout the process to pattern and remove the disposed layers or portions of those layers to form desired structures. For example, a typical step in integrated circuit manufacturing is the formation of a layer, such as a silicon oxide layer, on a wafer or substrate. Once such a layer is formed, it may be configured or modified (patterned and etched) and another layer may be disposed over it. Such layering continues until a succession of layers of different materials and geometries combine to produce thousands of very small electronic devices that function together as integrated circuits.

One method of forming and configuring a layer is to deposit the layer using a deposition process (e.g., chemical vapor deposition) and then etch the deposited layer. Etching typically includes removing portions of a layer to form a pattern. For example, an etch mask may be used to mask certain portions of the layer while exposing others to an etching component, thus transferring a pattern from the etch mask to the layer. Etching may include “wet etching” or “dry etching.” Wet etching typically includes dissolving an exposed portion of a deposited layer with a liquid solution. Dry etching is generally a more precise method of etching and includes the use of gas rather than liquid chemicals. Examples of dry etching include reactive ion etching (RIE), sputter etching, and vapor phase etching.

A typical integrated circuit manufacturing system includes a process chamber (e.g., a plasma reactor chamber for plasma etching or a deposition chamber) or various process chambers in which certain steps of the manufacturing process, such as layer deposition and etching, are performed. Disadvantageously, layer deposition and etching often result in particulate matter that builds up in the processing system. During operation, particulate matter accumulates in the chambers and in other areas of the system. For example, contaminants from the atmosphere or material that has been etched away from the wafer or layers disposed on the wafer frequently accumulates on process chamber walls and on chamber components. The amount of residue increases with each successive processing operation, which can result in variations in chamber conditions and corresponding variations in process performance. Build up of residue inside a processing chamber, over time, not only makes the process unreliable but also frequently results in degraded and defective wafers. For example, eventually, the accumulated material can detach and land on a wafer, which can potentially cause a defect in the final product.

Accordingly, it is common in the industry to remove unwanted deposition materials from process chambers using certain established cleaning techniques (e.g., cycle purges). However, while these cleaning techniques are beneficial, they can be inefficient and leave some residual build up. In fact, some cleaning processes leave residues of their own behind.

In view of the foregoing, it is desirable to improve established cleaning processes to increase the removal of residue from wafer processing systems.

### BRIEF DESCRIPTION OF THE DRAWINGS

Advantages of the invention may become apparent upon reading the following detailed description and upon reference to the drawings in which:

FIG. 1 is a simplified diagrammatic view of a semiconductor processing chamber with a sound emitting device in accordance with embodiments of the present invention;

FIG. 2 illustrates a graphical representation of actual experimental data demonstrating increased residue removal in accordance with embodiments of the present invention;

FIG. 3 is a diagram illustrating the cleaning efficiency of embodiments of the present technique; and

FIG. 4 is a flow chart illustrating a method for removing residue from a wafer processing system chamber in accordance with embodiments of the present technique.

### DETAILED DESCRIPTION OF SPECIFIC EMBODIMENTS

One or more specific embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

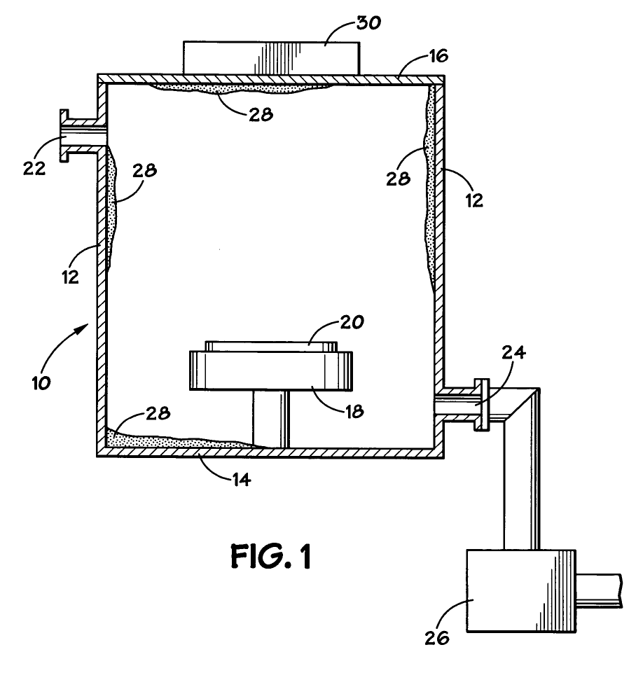

FIG. 1 is a simplified view of a semiconductor processing chamber in accordance with embodiments of the present invention. The chamber is generally indicated by reference number 10. The chamber 10 is defined by side walls 12, a base 14, and a top 16, wherein the side walls 12 extend between the base 14 and the top 16. In one embodiment, the chamber 10 is an etching chamber and the top 16 comprises a quartz or sapphire window. The chamber also includes a wafer support 18 on which a wafer 20 rests during processing.

In the illustrated embodiment, the chamber 10 includes an inlet port 22 and an exit port 24. The inlet and exit ports 22 and 24 may be utilized with a pump 26 in purge operations to remove particles from the chamber 10. For example, a gas (e.g., nitrogen or oxygen) may be fed into the chamber 10 via the inlet port 22 and continuously pumped out of the chamber 10 via the exit port 24 using the pump 26. Such a purge procedure may be utilized in accordance with the present embodiments to remove built-up residue 28 from the chamber 10 by flushing and carrying the particles forming the residue 28 out of the chamber 10 via the exit port 24. This purge operation may be one type of cleaning process that can be utilized in accordance with embodiments of the present invention. It should be noted that some purges (e.g., mild purges) may not rise to the level of a cleaning operation as understood by one of ordinary skill in the art. However, such mild purges may remove particulate matter from the chamber 10 nonetheless and may be utilized in accordance with embodiments of the present technique. Other known wafer or waferless cleaning recipes may also be utilized in accordance with the present techniques. For example, plasma cleaning operations may be employed or etchant gas may be introduced into the chamber 10 to facilitate removal of deposited materials from the chamber 10.

In accordance with the present embodiments, rather than performing a conventional cleaning operation, cleaning of the chamber 10 is performed by pumping gas through the chamber 10 (or utilizing an alternate cleaning recipe) in coordination with emitting sound from a sound emitting device 30. For example, sound waves may be emitted before or during a chamber purge. The sound emitting device 30 may include a sonic transducer or a plurality of sonic transducers that are coupled to the chamber 10. For example, in one embodiment the emitting device 30 includes eight separate transducers that are excited by a 40,000 Hz signal. In the illustrated embodiment, the sound emitting device 30 is coupled to an exterior portion of the top 16 of the chamber 10 to facilitate its use in cleaning procedures. In other embodiments, the sound emitting device 30 may be coupled to interior portions of the chamber 10 or both exterior and interior portions. Additionally, in some embodiments, the sound emitting device 30 may not be coupled to the chamber 10 at all. Rather, the sounding emitting device 30 may be positioned relative to the chamber 10 such that sound waves can be emitted into the chamber 10 from the sound emitting device 30.

The sound emitting device 30 is adapted to emit sound waves to physically vibrate the chamber 10, its components, and its contents. This physical vibration operates to break loose particles from the residue 28 built up in the chamber 10. When the sound emitting device 30 is utilized during chamber cleaning operations, this breaking up of the residue 28 allows the cleaning procedure to remove a significant amount of additional residue that may have otherwise been left in the chamber. In other words, the sound emissions enhance the cleaning operation. In some embodiments, the sound emitting device 30 may be utilized prior to initiation of a cleaning operation and/or during the cleaning operation to break up the residue and enhance cleaning.

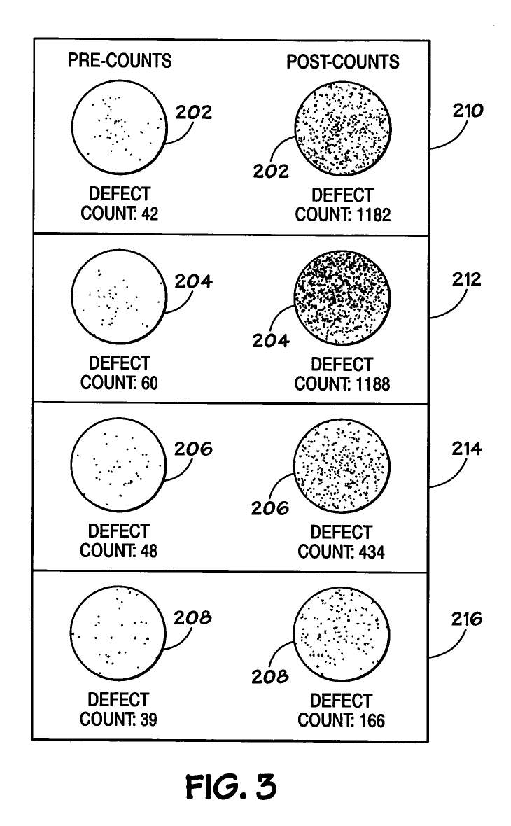

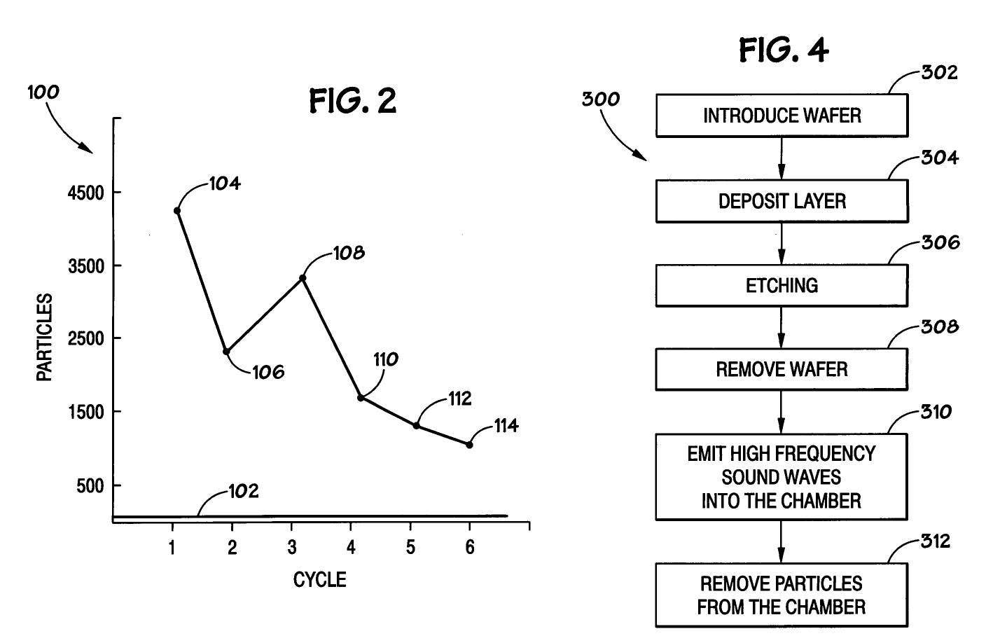

FIG. 2 is a graphical representation of actual experimental data demonstrating increased residue removal in accordance with embodiments of the present invention. The graph is generally referred to by reference number 100. The graph 100 includes a plot of number of particles removed per cleaning cycle versus consecutive number of cycles. The data in the graph 100 was obtained using eight 40,000 Hz transducers coupled to a window of a wafer chamber. The transducers were activated for thirty seconds during each of a number of purge cycles to improve residue removal. The number of particles removed was determined by a surface particle counter used to scan for defects on a wafer. Specifically, a wafer was passed through the chamber for each cycle and the number of particles disposed on the wafer while in the chamber was determined.

The graph 100 illustrates use of a cycle purge alone and a cycle purge in conjunction with thirty seconds of high frequency sound emissions for each of six consecutive cycles. As illustrated by line 102 in the graph 100, using only the cycle purge without sound emission resulted in removal of approximately 5 particles. The use of a line to represent this removal illustrates that the likely result would be approximately consistent for each cycle without sound emission, as would be appreciated by one of ordinary skill in the art.

In the first cycle wherein high frequency sound waves were emitted for thirty seconds in conjunction with the gas purge, almost one-thousand times as many particles were removed, as illustrated by data point 104. As this cleaning process continued for the rest of the cycles, the amount of particles removed per cycle slowly dropped to approximately 1,000 particles, as illustrated by data points 106, 108, 110, 112, and 114. Each of the data points 104, 106, 108, 110, 112, and 114, wherein high frequency sound emissions were used in conjunction with the purge, was higher that the purge alone.

The experimental data set forth in FIG. 2 indicates that the use of high frequency sound waves (e.g., 40,000 Hz) during a purge operation in accordance with present embodiments can improve the removal of particulate matter significantly. The initial spike in particle removal followed by a downward trend in particle removal suggests that introduction of sound waves during cleaning causes a drastic improvement in cleaning efficiency, which is supported by the reduced number of particles removed by successive cycles. Indeed, the use of sound waves in the first cleaning cycles apparently reduced the amount of particles in the chamber such that there were fewer particles to remove in later cleaning cycles. Further, the use of sound wave emissions clearly improved particle removal compared to using standard cleaning alone. This is illustrated by the contrast in using a cycle purge alone (line 102) and using a cycle purge in conjunction with sound emissions (data point 104-114).

While the data in FIG. 2 is representative of embodiments of the present technique wherein a standard cycle purge operation is utilized as the cleaning method, it will be recognized by those of ordinary skill in the art that various cleaning methods could be implemented in conjunction with such sound emissions to achieve improved results. Indeed, as set forth above, the sound emissions generally cause the residue 28 to break up, which facilitates its removal from the chamber 10. For example, breaking up the residue 28 may enable the residue 28 to be caught up and carried from the chamber in a flow of gas or it may allow a cleaning agent (e.g., an etchant) to more readily react with the particles forming the residue 28.

FIG. 3 is a diagram illustrating the cleaning efficiency of embodiments of the present technique. The data in FIG. 3 was determined using a surface particle counter to determine the number of particles on wafers before and after emitting twenty seconds of sonic waves during a plasma operation with the wafer present. The term “sonic” may refer to any wave frequency including ultrasonic, megasonic, and lower or higher frequencies. Specifically, FIG. 3 illustrates a number of detected particles (a defect count) on each of four wafers 202, 204, 206, and 208 for four successive cycles 210, 212, 214, and 216, wherein each of the cycles includes twenty second sonic emissions during plasma operations. For each of the four cycles, the defect count before the cycle is referred to as a “pre-count” and the defect count after the cycle is referred to as a “post-count.” For example, the pre-count for the wafer 202 was 42 particles and the post-count for the wafer 202 was 1,182 particles. The second, third, and fourth wafers 204, 206, and 208 had approximately the same pre-counts but the post-counts trend down for each respective cycle 212, 214, and 216. Indeed, the post-count for the wafer 208 in the last cycle was merely 166 particles. This suggests that particle removal is very efficient when using the sonic emissions in conjunction with the plasma procedure.

It should be noted that in some embodiments of the present technique, the emitted sound waves are of varying frequency (e.g., from 35 KHz to 45 KHz) and the sound emitting device 30 is configured to emit such a variable frequency. Additionally, in one embodiment, the sound emitting device may be configured to adjustably emit designated frequencies or a range of designated frequency. For example, the sound emitting device 30 may be configured to allow a user to designate a certain emission frequency or range of frequencies. Different frequencies may be more efficient than others in dislodging residue composed of certain materials and residue composed of particles with certain geometric features. For example, a certain high frequency sound wave may have some correspondence to a particular type of particulate matter forming the residue 28 such that the particular frequency causes the particles to resonate and break away from the build up more readily. Accordingly, embodiments of the present technique may be tuned to more efficiently agitate particulate matter forming the residue 28 and thus more readily break up and remove the residue 28.

In addition to facilitating residue removal, embodiments of the present technique may also facilitate other aspects of wafer processing. Indeed, in some embodiments of the present technique, the sound emitting device 30 operates to heat up the chamber 10, which may facilitate preparation for steady state operations. For example, the sound emitting device 30 may be coupled to a window of an etching chamber such that the window is heated up via vibrations caused by sound waves emitted from the sound emitting device 30. This may be beneficial because the sound waves can heat the chamber or components of the chamber more quickly than standard procedures. For example, a typical etching chamber may include an electrode disposed on a quartz window of the chamber, wherein the electrode is powered by a radio frequency (RF) supply. The purpose of the electrode may be to provide energy to create a plasma in the processing chamber 10. In many integrated circuit manufacturing processes, the plasma is heated up to get the chamber 10 to a steady state condition for processing. However, the chamber 10 is often difficult to heat because the electrodes are RF powered. Accordingly, embodiments of the present technique may be beneficial in such processes because the sound emitting device 30 can provide initial heating and/or supplemental heating of the chamber 10. Thus, heating efficiency may be increased.

FIG. 4 is a block diagram of a method for processing a wafer in a system and subsequently removing residue from the wafer processing system chamber in accordance with embodiments of the present technique. The method is generally referred to by reference number 300. Specifically, method 300 includes introducing a wafer into a chamber 302, depositing a layer on the wafer 304, etching the wafer or deposited layer 306, removing the wafer from the chamber 308, emitting high frequency sound waves into the chamber 310, and removing particles from the chamber 312. The particle removing operation 312 will typically include drawing or pushing residue particles out of the chamber or reacting with the particles. As discussed above, the sound wave emissions enhance such cleaning by breaking up residue in the chamber. In some embodiments, a dummy wafer may be introduced into the chamber prior to performing acts 310 and 312 to facilitate cleaning, as is known in the art. Further, it should be noted that some embodiments of the present invention include merely cleaning the chamber using high frequency sound wave emissions in conjunction with a cleaning procedure (e.g., a cycle purge) as represented by blocks 310 and 312.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method, comprising:
emitting sonic waves into a process chamber of a wafer processing system to dislodge accumulated particulate matter from the process chamber; and
removing the particulate matter from the process chamber.

2. The method of claim 1, comprising performing a waferless chamber cleaning operation coordinated with emitting the sonic waves.

3. The method of claim 1, comprising vibrating a panel of the process chamber with the sonic waves to heat the process chamber.

4. The method of claim 1, wherein emitting the sonic waves comprises emitting varying frequency sound waves.

5. The method of claim 1, comprising emitting a 40 KHz sound wave.

6. The method of claim 1, comprising emitting the sonic waves into the process chamber concurrently with a clean operation.

7. The method of claim 1, comprising processing a wafer in the process chamber.

8. The method of claim 1, comprising emitting the sonic waves for approximately 20-40 seconds during a cleaning process.

9. A processing chamber, comprising:
a cavity;
a chamber wall forming at least a portion of the cavity;
a chamber lid removably coupled to the chamber wall; and
an sonic wave emitting device configured to emit sonic waves into the cavity of the processing chamber to facilitate removal of accumulated particulate matter from therein.

10. The processing chamber of claim 9, comprising a cleaning system.

11. The processing chamber of claim 10, wherein the cleaning system comprises a gas feed port.

12. The processing chamber of claim 10, wherein the cleaning system comprises a gas exit port.

13. The processing chamber of claim 9, wherein the sonic wave emitting device comprises at least one sonic transducer.

14. The processing chamber of claim 9, wherein the sonic wave emitting device is coupled to the chamber lid.

15. The processing chamber of claim 9, wherein the chamber lid comprises a quartz plate.

16. A wafer processing system, comprising:
a deposition unit configured to dispose a layer on the wafer;
an etching unit configured to etch the wafer or layer; and
a high frequency sound emitting device configured to emit high frequency sound waves into the wafer processing system to break up residue built up within the system.

17. A method, comprising:
emitting sonic waves into a process chamber of a wafer processing system to dislodge accumulated particulate matter from the process chamber;
performing a clean operation on the process chamber during or after emitting the sonic waves; and
flushing the chamber.

18. A method, comprising:
flowing gas into a process chamber of a wafer processing system via a chamber inlet;
emitting sonic waves into the process chamber while flowing the gas into the process chamber to dislodge accumulated particulate matter from the process chamber; and
carrying the particulate matter from the process chamber with the gas flowing out of a chamber outlet.

19. The method of claim 18, comprising selecting a frequency of the sonic waves based on a type of residue present in the process chamber.

20. The method of claim 18, comprising vibrating a panel of the process chamber with the sonic waves to heat the process chamber.

21. The method of claim 18, comprising emitting the sonic waves into the process chamber prior to flowing the gas into the process chamber.
